(19) United States
(12) Patent Application Publication
(10) Pub. No.: US 2018/0257951 A1
(43) Pub. Date: Sep. 13, 2018

(54) Solar collector apparatus

(71) Applicants: Behrooz Shahriari, Shahinshahr (IR); Ehsan Seyfali, Kermanshah (IR)

(72) Inventors: Behrooz Shahriari, Shahinshahr (IR); Ehsan Seyfali, Kermanshah (IR)

(21) Appl. No.: 15/920,435

(22) Filed: Mar. 13, 2018

Related U.S. Application Data
(63) Continuation-in-part of application No. PCT/IB2016/050149, filed on Jan. 13, 2016.

(30) Foreign Application Priority Data
Nov. 5, 2015 (IR) 13945014000300882

(51) Int. Cl. C02F 1/14; H02S 99/00; H01L 31/042

(52) U.S. Cl. CPC C02F 1/14; C02F 2303/04; H01L 31/042; H02S 99/00

(57) ABSTRACT

An apparatus and method for simultaneous water disinfection and electricity generation includes a disinfection section and an electricity generating section. In some cases, the disinfection section includes a storage tank and a plurality of transparent vacuum tubes. In addition, the electricity generating section includes a base plate and a plurality of photovoltaic cells. Water disinfection is performed by exposing the disinfection section to sunlight radiation. Electricity generation is carried out by exposing the electricity generating section to the sunlight passing through the plurality of transparent vacuum tubes of the disinfection section.

### CROSS-REFERENCE TO RELATED APPLICATION

This application claims the benefit of priority from international Application No. PCT/IB2016/050149, filed Jan. 13, 2016, and entitled “INTEGRATED SOLAR HEAT AND POWER GENERATION,” which is incorporated herein by reference in its entirety.

### TECHNICAL FIELD

The present disclosure generally relates to solar collecting and disinfecting systems and methods, and particularly to integrated solar photovoltaic collector and water disinfection.

### BACKGROUND

A large part of the world still lacks safe drinking water. The world health organization (WHO) estimates that roughly 1.1 billion people in developing countries do not have access to potable drinking water, and 2 million die every year due to drinking water-related diseases. Children are more vulnerable; every day the world loses roughly 3900 children below age 5. A third of people living in rural areas, slums and poor suburbs in developing countries use streams, ponds, rainwater from roofs and poorly constructed wells that can be contaminated with pathogens. The majority of contamination originates from human and animal fecal matter that, due to poor sanitation, ends up in streams and wells. This is mostly an issue within the developing regions, but also can become an issue in industrialized nations in times of war, or natural disasters such as floods, earthquakes, tsunamis, or any time civil unrest or terrorism disrupts centrally distributed and disinfected tap water, whose systems often rely heavily on chemicals and electric power.

It is known that direct solar radiation is one energy source that is capable of disinfecting water. There are numerous methods and devices for direct solar-based water disinfection. These usually utilize one or more bands of naturally occurring radiation comprised of thermal (infrared), visible, and/or ultraviolet light energy. The thermal disinfection mechanism is characterized by sufficiently heating the water for some minimum duration and at some minimum temperature to induce pasteurization of the water. The non-thermal disinfection mechanism is characterized by sufficiently exposing the DNA and/or RNA of the micro-organism to photon energies that can impart direct dissociation of the chemical compounds that are the “building blocks” of the DNA/RNA chain, thereby breaking the cellular replication cycle and continued growth of the organism.

There exists a well-known, simple, very low-cost, and effective solution that can save lives by purifying the water using natural sunlight; this is known as the SODIS (SOlar Disinfections) method. The SODIS method treats the contaminated water through several synergistic mechanisms: radiation of the infrared spectrum, increase in water temperature, and some limited oxidation from the interaction of light with dissolved oxygen. It has been shown that if the water temperature rises to as little as 50° C., the disinfection process is three times faster than otherwise achievable without the thermal enhancement mechanism.

However, the SODIS technology may be associated with some challenges, for example, the standard SODIS technology utilizes used P.E.T plastic bottles. Reuse is encouraged to provide an essentially no-cost source of containersA detrimental side of this, however, is that recent evidence shows that heating plastic-bottled water is a potentially unsafe practice due to release from the plastic of cancer-causing and endocrine disrupting compounds. Hence, the more immediate life-saving benefits of SODIS water treatment are compromised by the long-term risk effects of chemical poisoning.

On the other hand, energy may be one of the most important issues that need to be focused very aggressively upon. The energy can be considered as a resource that has various applications almost in every sector like industrial, agricultural, medical, transportation, household and so on. The availability and accessibility of energy are very important for growth of the individual and development of every country. As the whole world will be facing scarcity of fossil fuels like coal, natural gas, and oil in the near future, it seems to be very important to find and develop some renewable energy resources. Solar energy, which is clean and available freely and in abundant quantity, is considered as one of the most efficient choices for renewable energy resources. Solar energy can also be easily converted into various other usable forms of energy like thermal energy, electrical energy, and chemical energy.

Currently, it is widespread practice to install a photovoltaic cell or a heat collection panel (solar water heater and the like) on a roof or the like of a building for effective use of sunlight, to thereby reduce gas and electricity consumption. A heat collection panel, which utilizes heat from sunlight, is completely different in construction and functionality from that of a photovoltaic cell, which utilizes sunlight as electric power by photoelectric conversion.

However, a roof or the like that is well exposed to sunlight may be limited in area. Few buildings have a roof or the like wide enough to allow installation of a heat collection panel and a photovoltaic cell side by side. On the other hand, it is desired that both heat and light of sunlight be effectively utilized for retaining the global environment. To address such a problem, there is known a photovoltaic power generation and solar heat collector with a hybrid construction of a photovoltaic cell and a heat collection panel to enable effective utilization of both light energy and heat energy from sunlight. Conventional panel solar collectors are, generally, expensive, primarily because they contain a large number of silicon solar cells. A typical photovoltaic panel producing approximately 250 W of electrical power contains approximately 20 square feet of silicon solar cells, which require solar grade silicon (e.g., 6N purity).

However, photovoltaic panels may be associated with some issues such as wasting or otherwise not using any infrared spectrum of the sunlight. On the other hand, solar heat collectors create additional cost, because they need a facility for substituting heated water with water contained in a tank in order to enable all the water to be heated.

Therefore, there is a need for solar disinfection systems and devices in which water disinfection and solar energy collecting are accomplished simultaneously and in a cost-effective and healthy way.

### SUMMARY

This summary is intended to provide an overview of the subject matter of the present disclosure, and is not intended to identify essential elements or key elements of the subject matter, nor is it intended to be used to determine the scope of the claimed implementations. The proper scope of the present disclosure may be ascertained from the claims set forth below in view of the detailed description below and the drawings.

In order to achieve more efficient solar energy collecting, an integrated apparatus is utilized to provide a facility for disinfecting water and generating electricity simultaneously. Utilizing the disclosed apparatus may provide certain cost and efficiency advantages relative to other solar collecting apparatuses.

In one general aspect, the present disclosure is directed to a solar collecting apparatus for disinfecting water and generating electricity simultaneously. The disclosed solar collector apparatus includes a disinfection section configured to disinfect water. The disinfection section includes a storage tank configured to preserve water. The disinfection section further includes a plurality of transparent vacuum tubes configured such that the water contained in the plurality of transparent vacuum tubes is heated and disinfected in response to exposure of the plurality of transparent vacuum tubes to sunlight radiation. In an aspect of the present disclosure, the plurality of transparent vacuum tubes are in fluid communication with the storage tank in a parallel configuration such that the water contained in the plurality of transparent vacuum tubes is replaced by the lower-temperature water contained in the storage tank through a thermosyphon exchanging mechanism in response to heating of the water contained in the plurality of transparent vacuum tubes by the sunlight radiation. The disinfection section further is constructed with a first securing angle between the plane of the transparent vacuum tubes and a first reference plane that is in a range between 0° and 90°. In another aspect of the present disclosure, the disclosed solar collector apparatus includes an electricity generating section configured to generate electricity in response to exposure of the electricity generating section to sunlight radiation. The electricity generating section includes at least a photovoltaic cell configured to generate electricity in response to exposed sunlight radiation. The electricity generating section further includes a base plate upon which the photovoltaic cell is mounted. The electricity generating section even further includes a mirror secured next to the disinfection section in a configuration such that the mirror increases intensity of sunlight radiation on the plurality of transparent vacuum tubes. In an aspect of the present disclosure, the mirror is mounted with a second securing angle that is in a range between between 40° and 150° relative to the plane of the vacuum tubes, and the disinfection section is placed in front of the electricity generating section, to apply filtering of the sunlight by absorbing an infrared spectrum of the sunlight radiation. The filtering further includes transition of the filtered radiation to the photovoltaic cell.

A counterpart method may be performed by preserving water in a storage tank; exposing water within a plurality of transparent vacuum tubes to sunlight to heat and disinfect the water; maintaining the vacuum tubes in fluid communication with the storage tank; enabling the heated and disinfected water in the plurality of transparent vacuum tubes to be replaced by lower-temperature water contained in the storage tank through a thermosyphon exchanging mechanism; and exposing at least one photovoltaic cell behind the plurality of transparent vacuum tubes to generate electricity.

One or more implementations may include enhancing intensity of sunlight to the transparent tubes using at least one mirror.

### BRIEF DESCRIPTION OF THE DRAWINGS

The drawing figures depict one or more implementations in accord with the present teachings, by way of example only, not by way of limitation. In the figures, like reference numerals refer to the same or similar elements.

FIG. 1 illustrates an implementation of a solar collector apparatus used in accord with the teachings herein to disinfect water and collect photovoltaic solar energy simultaneously.

### DETAILED DESCRIPTION

In the following detailed description, numerous specific details are set forth by way of examples in order to provide a thorough understanding of the relevant teachings. However, it should be apparent that the present teachings may be practiced without such details. In other instances, well-known methods, procedures, components, and/or circuitry have been described at a relatively high-level, without detail, in order to avoid unnecessarily obscuring aspects of the present teachings. The following detailed description is presented to enable a person skilled in the art to make and use the methods and devices disclosed in exemplary embodiments of the present disclosure. For purposes of explanation, specific nomenclature is set forth to provide a thorough understanding of the present disclosure. However, it will be apparent to one skilled in the art that these specific details are not required to practice the disclosed exemplary embodiments. Descriptions of specific exemplary embodiments are provided only as representative examples. Various modifications to the exemplary implementations will be readily apparent to one skilled in the art, and the general principles defined herein may be applied to other implementations and applications without departing from the scope of the present disclosure. The present disclosure is not intended to be limited to the implementations shown but is to be accorded the widest possible scope consistent with the principles and features disclosed herein.

As noted above, solar systems are able to utilize a part of the sunlight spectrum to generate electricity through solar heat collectors and photovoltaic panels. The solar systems, generally, utilize an ultraviolet and visible spectrum of sunlight in order to generate electricity through photovoltaic panels. A typical flat photovoltaic panel (PV) converts approximately 15-20% of the incident radiant energy into electricity, and a typical flat panel thermal energy collector converts approximately 50% of the incident radiant energy into heat.

In case of discrete solar energy collecting devices for electricity generation, heat collection, and water disinfection, a decrease in the efficiency of solar energy collecting systems may occur. This decrease in efficiency is substantially due to the waste of some spectrum of the sunlight in each of the discrete solar energy collecting devices. The system described herein more effectively and more healthily generates electricity, collects heat, and disinfects water by utilizing sunlight spectrum. As will be discussed below, this can allow significant improvement and cost-effectiveness issues in the operation of solar energy collecting systems by offering an integrated structure of photovoltaic panels and heat collecting devices.

The present disclosure is directed to a solar energy collector that is able to generate electricity and disinfect water simultaneously. In the solar collector system of the present disclosure, in order to increase efficiency, a disinfection section may be integrated with an electricity generation section. This may result in an efficiency increase. In some implementations, the disinfection section may include a storage tank and a plurality of transparent vacuum tubes. For purpose of reference, it should be understood that the water contained in the plurality of transparent vacuum tubes may be disinfected and heated, in response to the plurality of transparent vacuum tubes exposed to sunlight radiation. A transparent vacuum tube, generally, may include a main tube and a vacuum section (section within which a vacuum has been produced) encompassing the main tube. The vacuum section of a transparent vacuum tube may allow radiation to pass through the main tube but may minimize or prevent heat transfer between the main tube and the environment.

Benefits from utilizing transparent vacuum tubes in the disinfection section may include but are not limited to increased temperature of the water contained in the plurality of transparent vacuum tubes. This increase in temperature may be due to infrared radiation of sunlight passing through the plurality of transparent vacuum tubes. According to another aspect of this implementation, each of the plurality of transparent vacuum tubes may include a vacuum section that encompasses the main tube. In some implementations, the vacuum section of the plurality of transparent vacuum tubes may help minimize or prevent heat transfer between the water contained in the plurality of transparent vacuum tubes and the environment. Benefits from preventing heat transfer between the water contained in the plurality of transparent vacuum tubes and the environment may include but are not limited to increased efficiency, for example by retaining the water temperature contained in the plurality of transparent vacuum tubes. It should be understood that the temperature difference between the water contained in the plurality of transparent vacuum tubes and the water contained In the storage tank may cause the increased-temperature water in the plurality of transparent vacuum tubes to become replaced by the lower-temperature water contained in the storage tank due to a so-called thermosyphon effect. The thermosyphon effect may promote continuous substitution of the high-temperature water contained in the plurality of transparent vacuum tubes with the low-temperature water contained in the storage tank. This may provide a mechanism for the solar collector apparatus to disinfect all the water contained in the storage tank without resorting to any electrical equipment such as an electric pump for circulating the increased-temperature water in the plurality of transparent vacuum tubes and the lower-temperature water contained in the storage tank.

In some other implementations of the present disclosure, the disclosed solar disinfection system may further include an electricity generating section. The electricity generating section may comprise a plurality of photovoltaic cells that are capable of generating electricity in response to exposure to sunlight radiation. A photovoltaic cell, or “solar cell,” is generally an electrical device that converts the energy of light directly into electricity by the photovoltaic effect, which is a physical and chemical phenomenon. It is a form of photoelectric cell, which is a device whose electrical characteristics, such as current, voltage, or resistance, vary when exposed to light. Photovoltaic cells are the building blocks of photovoltaic modules, otherwise known as solar panels. Photovoltaic cells may be described as being photovoltaic, whether the source is sunlight or artificial light. They may be used as a photodetector, detecting light, or other electromagnetic radiation near the visible range, or measuring light intensity.

In some implementations, the electricity generating section may be configured in a way such that the electricity generating section is exposed to sunlight radiation after the disinfection section. This implementation can provide significant benefits, including but not limited to a decrease in cost and thereby an increase in efficiency through integrating the electricity generating mechanism with the water disinfection mechanism. Another significant benefit that may be provided by this implementation is in an increase of photovoltaic cells efficiency by preventing the plurality of photovoltaic cells from being overheated. As noted above, the vacuum section of the plurality of the transparent vacuum tubes may help minimize or prevent water heat transfer to the plurality of photovoltaic cells. It should be understood that temperature increase in a photovoltaic cell can substantially decrease photovoltaic cell efficiency.

In the present disclosure, the electricity generating section is located in a place where sunlight radiation may reach the electricity generating section after passing through the plurality of transparent vacuum tubes of the disinfection section. Hence, when the sunlight radiation passes through the plurality of transparent vacuum tubes of the disinfection section, the infrared spectrum of the sunlight radiation may attenuate or otherwise be filtered by the water contained in the plurality of transparent vacuum tubes. Consequently, as the sunlight radiation reaches the plurality of photovoltaic cells of the electricity generating section, the sunlight radiation excludes infrared spectrum that increase the temperature of the plurality of photovoltaic cells and do not produce any photovoltaic effect. Furthermore, as noted above, the vacuum section of the plurality of the transparent vacuum tubes may help minimize or prevent water heat transfer to the plurality of photovoltaic cells.

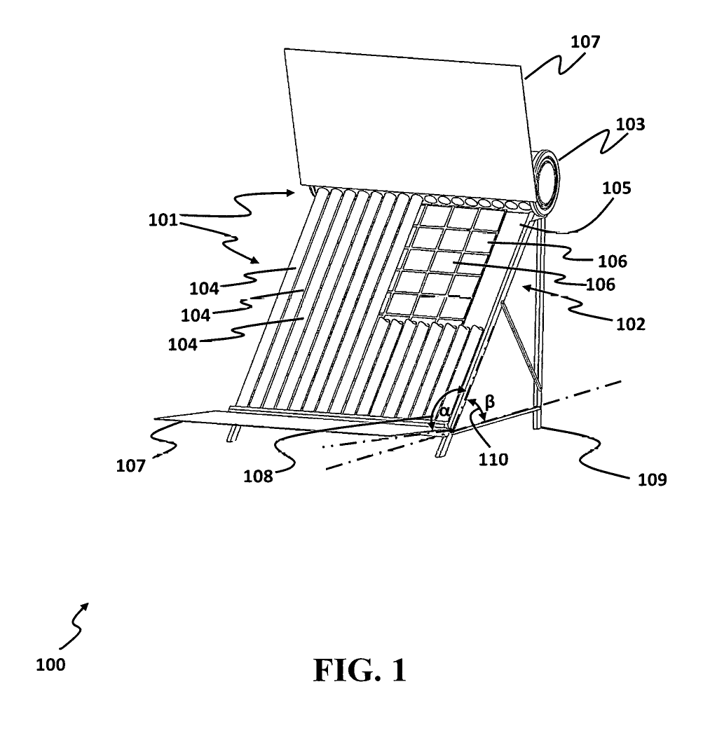

In order to provide greater clarity on the implementations disclosed herein, additional details are now provided with respect to the FIG. 1. Referring to FIG. 1, one implementation of a solar collector apparatus 100 that may be utilized to provide a facility for disinfecting the water and generating electricity simultaneously is depicted. The solar collector apparatus 100 may include a disinfection section 101 and an electricity generating section 102. In one aspect, the disinfection section 101 may be configured to disinfect contaminated water. In some implementations, the disinfection section 101 may include a storage tank 103 and a plurality of transparent vacuum tubes 104. The plurality of transparent vacuum tubes 104 may be in fluid communication with the storage tank 103. In different implementations, the plurality of transparent vacuum tubes 104 may be secured in an array in a parallel configuration or, alternatively, in a series configuration.

In some implementations, when the plurality of transparent vacuum tubes 104 are exposed to sunlight, the infrared spectrum of the sunlight may be absorbed by the water. The infrared spectrum of the sunlight may disinfect and heat the water contained in the plurality of transparent vacuum tubes 104. It should be understood that that heated water in the plurality of transparent vacuum tubes 104 may be replaced by the lower-temperature water contained in the storage tank 103 due to the thermosyphon effect. Consequently, a new volume of water is exposed to the sunlight radiation and, similarly, the infrared spectrum of the sunlight may be absorbed by the new volume of water. The infrared spectrum of the sunlight may disinfect and heat the new volume of water now contained in the plurality of transparent vacuum tubes 104. It should be understood that the temperature difference between the water contained in the plurality of transparent vacuum tubes 104 and in the water contained in the storage tank 103 will tend to cause water circulation that helps disinfecting and heating all water contained in storage tank 103 and the plurality of transparent vacuum tubes 104.

In some implementations, in order to utilize other spectrums of the sunlight (other than the infrared spectrum), the electricity generating section 102 may be secured next to the disinfection section 101. In one implementation, the electricity generating section 102 may include a base plate 105 and a plurality of photovoltaic cells 106 mounted in a matrix configuration on the base plate 105. In different implementations, the plurality of photovoltaic cells 106 may be mounted or otherwise attached to the base plate 105 in any configuration and by any attaching mechanism.

As noted above, in different implementations, the sunlight may reach the plurality of photovoltaic cells 106 of the electricity generating section 102 after passing through the plurality of transparent vacuum tubes 104 of the disinfection section 101. These implementations can provide significant benefits including, but not limited to, an increase in electricity generating section 102 efficiency by preventing infrared spectrum incidence to the plurality of photovoltaic cells 106. It should be understood that the efficiency of the electricity generating section 102 is substantially dependent on temperature of the plurality of photovoltaic cells 106; and the infrared spectrum may increase the temperature of the plurality of photovoltaic cells 106 without producing any photovoltaic effect.

In order to augment the sunlight intensity to which the solar collector apparatus 100 is exposed, in some implementations, a plurality of mirrors may be utilized. In different implementations, each of the plurality of mirrors may include various shapes (flat, concave, convex, or any other shape). For example, in one implementation, the solar collector apparatus 100 may include flat mirrors 107. The flat mirrors 107 may be mounted or otherwise attached to the solar collector apparatus 100 in a configuration such that the flat mirrors 107 are able to reflect the sunlight such that intensity of total sunlight radiating to the plurality of transparent vacuum tubes 104 is increased.

Furthermore, a first securing angle (α) 108 may be established for each flat mirror 107. The first securing angle (α) 108 is the angle between the flat mirror 107 and the base plate 105 defining a first reference plane. The first securing angle (α) 108 may be determined by an operator. It should be understood that the sunlight radiation angle and the sunlight radiation intensity are variables that may vary during day and night and during the year. Furthermore, the sunlight radiation angle and the sunlight radiation intensity may be changed when the geographical location of the solar collector apparatus 100 is changed. Consequently, the operator may assign the first securing angle (α) 108 according to the time and/or location and/or other conditions. In some alternative implementations, the flat mirrors 107 may be associated with an intelligent light detector system that automatically assigns the first securing angle (α) 108 according to the time and/or location and/or other conditions and then secures the flat mirror 107 at the determined angular position.

In order to help the solar collector apparatus 100 stand firmly, a mounting assembly 109 may be utilized. In some implementations, the mounting assembly may be configured to help the solar collector apparatus 100 remain secured in a determined angular position relative to the sunlight radiation.

Furthermore, a second securing angle (β) 110 may be established between a reference plane, which may be horizontal, and a plane of the base plate 105. The second securing angle (β) 110 may be determined by an operator. As noted above, it should be understood that the sunlight radiation angle and the sunlight radiation intensity are variables that may vary during day and night and during the year. Furthermore, the sunlight radiation angle and the sunlight radiation intensity may be changed whenever the geographical location of the solar collector apparatus 100 is changed. Consequently, the operator may assign the second securing angle (β) 108 according to the time and/or location and/or other conditions. In some alternative implementations, the base plate 105 may be associated with an intelligent light detector system that automatically assigns the second securing angle (β) 110 according to the time and/or location and/or other conditions and then secures the base plate 105 in determined angular position.

As presented herein, the disclosed system and apparatus can provide a facility for collecting solar energy by means of a maximally efficient procedure. The integrated configuration of the disclosed solar collector apparatus makes it possible to disinfect water and generate electricity with high efficiency. When the disclosed solar collector apparatus is exposed to sunlight, the sunlight directly radiates the plurality of vacuum tubes of the water disinfection system. As an obvious consequence of exposing the water to sunlight, especially the infrared spectrum of the sunlight, the water is heated and disinfected by absorbing infrared spectrum of the sunlight radiation. The filtered sunlight radiation in the infrared spectrum is attenuated or filtered, then radiates to the plurality of photovoltaic cells of the electricity generating section. As an obvious consequence of exposing a photovoltaic cell to sunlight, especially ultraviolet and visible spectrum of the sunlight, the plurality of photovoltaic cells of the electricity generating section generate electricity.

Furthermore, in one or more implementation of the present disclosure, utilizing the plurality of vacuum tubes can help increasing the electricity generating section efficiency by preventing the plurality of photovoltaic cells overheat, in two ways. First, the water contained in the plurality of vacuum tubes may filter the infrared spectrum of the sunlight before radiating to the plurality of photovoltaic cells. And second, the vacuum section of the plurality of vacuum tubes may minimize or otherwise prevent the heat transfer between the heated water contained in the plurality of vacuum tubes and the plurality of photovoltaic cells.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

The scope of protection is limited solely by the claims that now follow. That scope is intended and should be interpreted to be as broad as is consistent with the ordinary meaning of the language that is used in the claims when interpreted in light of this specification and the prosecution history that follows and to encompass all structural and functional equivalents. Notwithstanding, none of the claims are intended to embrace subject matter that fails to satisfy the requirement of Sections 101, 102, or 103 of the Patent Act, nor should they be interpreted in such a way. Any unintended embracement of such subject matter is hereby disclaimed.

Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study, except where specific meanings have otherwise been set forth herein. Relational terms such as “first” and “second” and the like may be used solely to distinguish one entity or action from another without necessarily requiring or implying any actual such relationship or order between such entities or actions. The terms “comprises,” “comprising,” or any other variation thereof, as used herein and in the appended claims are intended to cover a non-exclusive inclusion, encompassing a process, method, article, or apparatus that comprises a list of elements that does not include only those elements but may include other elements not expressly listed to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is not intended to be used to interpret or limit the scope or meaning of the claims. In addition, in the foregoing Detailed Description, it can be seen that various features are grouped together in various implementations. Such grouping is for purposes of streamlining this disclosure and is not to be interpreted as reflecting an intention that the claimed implementations require more features than are expressly recited in each claim. Rather, as the following claims reflect, inventive subject matter lies in less than all features of a single disclosed implementation. Thus, the following claims are hereby incorporated into this Detailed Description, with each claim standing on its own as a separately claimed subject matter.

While various implementations have been described, the description is intended to be exemplary, rather than limiting and it will be apparent to those of ordinary skill in the art that many more implementations are possible that are within the scope of the implementations. Although many possible combinations of features are shown in the accompanying figures and discussed in this detailed description, many other combinations of the disclosed features are possible. Any feature of any implementation may be used in combination with or substituted for any other feature or element in any other implementation unless specifically restricted. Therefore, it will be understood that any of the features shown and/or discussed in the present disclosure may be implemented together in any suitable combination. Accordingly, the implementations are not to be restricted except in the light of the attached claims and their equivalents. Also, various modifications and changes may be made within the scope of the attached claims.

What is claimed is:

1. An apparatus for simultaneous water disinfection and electricity generation, the apparatus comprising:
a disinfection section configured to disinfect water in response to exposure of the disinfection section to sunlight radiation, the disinfection section including:
at least a storage tank configured to preserve water, and
a plurality of transparent vacuum tubes in fluid communication with the storage tank, water contained in the plurality of transparent vacuum tubes being heated and disinfected in response to exposure of the plurality of transparent vacuum tubes to sunlight radiation, heated and disinfected water in the plurality of transparent vacuum tubes being replaced by lower-temperature water contained in the storage tank through a thermosyphon exchanging mechanism, the plurality of transparent tubes arranged in a parallel configuration at a first securing angle of between 0° and 90° between a plane of the vacuum tubes and a reference plane;
an electricity generating section configured to generate electricity in response to exposure of the electricity generating section to sunlight radiation, the electricity generating section including:
at least a photovoltaic cell configured to generate electricity in response to exposure of the photovoltaic cell to sunlight radiation, the photovoltaic cell disposed behind the plurality of transparent vacuum tubes, water in the plurality of transparent vacuum tubes absorbing an infrared spectrum of the sunlight radiation before the sunlight radiation reaches the photovoltaic cell; and
a mirror secured next to the disinfection section in a configuration such that the mirror increases the sunlight radiating the plurality of transparent vacuum tubes in intensity, the mirror mounted with a second securing angle of between 40° and 150° relative to the plane of the vacuum tubes.

2. An apparatus for disinfecting water, the apparatus comprising:
at least a storage tank configured to preserve water, and
a disinfection section including a plurality of transparent vacuum tubes in fluid communication with the storage tank, water contained in the plurality of transparent vacuum tubes being heated and disinfected by exposure of the plurality of transparent vacuum tubes to sunlight.

3. The apparatus of claim 2, wherein heated and disinfected water in the plurality of transparent vacuum tubes is replaced by lower-temperature water contained in the storage tank through a thermosyphon exchanging mechanism, the plurality of transparent tubes arranged in a parallel configuration with a first securing angle between 0° and 90° relative to a reference plane.

4. The apparatus of claim 2, wherein the apparatus includes a mirror secured next to the disinfection section in a configuration such that the mirror increases intensity of the sunlight radiating the plurality of transparent tubes.

5. The apparatus of claim 7, wherein the mirror includes a second securing angle that is between 40° and 150° relative to a plane of the tubes.

6. The apparatus of claim 2, wherein at least one of the plurality of transparent tubes is a transparent vacuum tube.

7. The apparatus of claim 1, wherein the reference plane is horizontal.

8. The apparatus of claim 6, further comprising:
at least a photovoltaic cell configured to generate electricity in response to exposure of the photovoltaic cell to sunlight radiation, the photovoltaic cell disposed behind the plurality of transparent vacuum tubes, water in the plurality of transparent vacuum tubes absorbing an infrared spectrum of the sunlight radiation before the sunlight radiation reaching the photovoltaic cell.

9. A method of disinfecting water, comprising the steps of:
preserving water in a storage tank;
exposing water within a plurality of transparent vacuum tubes to sunlight to heat and disinfect the water;
maintaining the vacuum tubes in fluid communication with the storage tank;
enabling the heated and disinfected water in the plurality of transparent vacuum tubes to be replaced by lower-temperature water contained in the storage tank through a thermosyphon exchanging mechanism; and
exposing at least one photovoltaic cell behind the plurality of transparent vacuum tubes to light passing through the vacuum tubes to generate electricity.

10. The method of claim 9, including enhancing intensity of sunlight to the transparent tubes using at least one mirror.
